(19) United States
(12) Patent Application Publication
(10) Pub. No.: US 2006/0292302 A1
(43) Pub. Date: Dec. 28, 2006

(54) Apparatus and method for growing a synthetic diamond

(76) Inventors: Robert Chodelka, Sarasota, FL (US); Hexiang Zhu, Sarasota, FL (US); Reza Abbaschian, Gainesville, FL (US); Nikolay Patrin, Sarasota, FL (US); Alexander Novikov, Sarasota, FL (US)

Correspondence Address: NATH & ASSOCIATES, 112 South West Street, Alexandria, VA, 22314, US

(21) Appl. No.: 11/165,531

(22) Filed: Jun. 24, 2005

(51) Int. Cl. C01B 31/06; C23C 16/00; C23C 14/00

(52) U.S. Cl. 427/248.1; 423/446; 427/523

(57) ABSTRACT

Disclosed herein is an apparatus and method for growing a synthetic diamond. The apparatus for growing a synthetic diamond comprises: a reaction area contained with a high pressure, high temperature apparatus; and a means for pulling a vacuum on the reaction area. The method for growing a synthetic diamond includes the steps of using a reaction area contained within a high pressure, high temperature apparatus; and pulling a vacuum on the reaction area.

### BACKGROUND OF THE INVENTION

1. Field of the Invention

The present invention relates to a method and apparatus for producing synthetic diamonds.

2. Description of the Prior Art

Synthetic diamonds are manufactured by a process of applying extreme pressure (e.g., 65 kilobars) to a quantity of a carbon source disposed within a container, and heating the container under pressure to a sufficient temperature wherein the diamond is thermodynamically stable. A high pressure, high temperature apparatus is often used to apply the necessary pressure and heat to the carbon source to achieve conversion of the graphite to the more thermodynamically stable diamond.

The synthesis of diamond crystals by high pressure, high temperature processes has become well established commercially. Diamond growth in high pressure, high temperature processes occurs by the diffusion of carbon through a thin metallic film of any of a series of specific catalyst-solvent materials. Although such processes are very successfully employed for the commercial production of industrial diamond, the ultimate crystal size of such diamond growth is limited by the fact that the carbon flux across the catalyst film is established by the solubility difference between graphite and the diamond being formed. This solubility difference is generally susceptible to significant decrease over any extended period due to a decrease in pressure in the system and/or poisoning effects in the graphite being converted.

While most commercial processes for synthesizing diamonds produce small or relatively small particles, there are processes known for producing much larger diamonds. These processes generally involve producing the diamond in a reaction vessel in which a predetermined temperature gradient between the diamond seed material and the source of carbon is created. The diamond seed material is at a point at which the temperature of the reaction medium will be near the minimum value while the source of carbon is placed at a point where the temperature will be near its maximum. A layer of diamond nucleation suppressing material and/or an isolating material is interposed between the mass of metallic catalyst/solvent and the diamond seed material.

Very carefully adjusting pressure and temperature and utilizing relatively small temperature gradients with extended growth times can produce larger diamonds produced by using the high pressure, high temperature apparatus. Attempts to reliably produce very high quality diamond growth, however, have presented a number of mutually exclusive, yet simultaneously occurring problems. These problems include the strong tendency for spontaneous nucleation of diamond crystals near the diamond seed material (which occurs with an increase in the temperature gradient over the “safe” value). If the growth period is extended to produce diamond growth from the seed of greater than about 1/20 carat in size, the nucleated growth competes with the growth from the diamond seed with subsequently occurring collisions of multiple crystals that result in stress fractures within the grown crystals. Another problem is the partial or complete dissolution of the diamond seed material in the melted catalyst-solvent metal during that part of the process in which the catalyst-solvent medium becomes saturated with carbon from the nutrient source and then melts. Such dissolution produces uncoordinated diamond growth proceeding from spaced loci, which growths upon meeting, result in subsequent confused, flaw-filled growth of the diamond crystal.

In addition to overcoming the problems of spontaneous nucleation of diamond and diamond seed dissolution, it is highly desirable to be able to exercise reproducible control over the diamond growth process and, thereby, be able to produce novel diamond products, e.g. diamonds having unique color patterns and characteristics as well as affording the possibility of optimizing one or more physical properties in a given diamond.

Many apparatuses and systems have been developed for making synthetic diamonds with the aim of producing stones of unique color and characteristics. For example, Kendall, in U.S. Pat. No. 3,914,078, discloses generation of ultra-high pressures by a pair of opposed Bridgeman-type anvils. The generation of pressure is improved by surrounding the major portions of each anvil with a frustro-conical segmented jacket in position to transmit vertical forces thereon to the anvils in an axial direction and at the same time induce lateral compressive stresses therein for increasing the resistance thereof to brittle failure. Additional support is provided to the pressure-face ends of the anvils by a die ring laterally disposed therebetween in position to be circumferentially stressed by a segmented die ring which is, in turn, similarly compressed by a band of pressure-transmitting metal subjected to lateral extrusion by an annular piston enclosing the pressure system. The displacement of the piston is adjustably controlled in accordance with the size of the anvils and the axial forces thereon to provide optimum support to the die ring.

Strong, in U.S. Pat. No. 4,301,134, discloses diamond crystals of controlled impurity content and/or impurity distribution and reaction vessel configurations for the production thereof. Combinations of “dopant”, “getter” and “compensator” materials are employed to produce gemstones of unusual color patterns, or zoned coloration, using specific reaction vessel configurations. The reaction vessel configurations include a pair of punches and an intermediate belt or die member. The die member defines a centrally-located aperture and, together with the punches, defines two annular volumes to which pressure may be applied.

Ishizuka, in U.S. Pat. No. 4,518,334, discloses a high temperature high pressure apparatus which comprises: an annular die having a straight cylindrical bore and a substantially conical face in adjacency outwards with each end thereof, a pair of tapered punches which are in opposed and axial alignment with the die so that a conical face of each punch is substantially in parallel with that of the die, a pair of inner gaskets, each of which is made of fired refractory and arranged in direct abutment on the conical face of the punch and the bore of the die, a pair of outer gaskets, which are made of material of intermediate hardness level and arranged in adjacency outside the inner gasket, and a pair of stopper rings of readily deformable but highly tough material and arranged in adjacency outwards to the outer gaskets. The high temperature high pressure apparatus is used in the production of synthetic diamonds or cubic boron nitride.

Frushour, in U.S. Pat. No. 5,244,368, discloses a high pressure/high temperature piston-cylinder-type apparatus having an electrically insulating diamond or cubic boron nitride coating disposed between one or both movable pistons and the surrounding core to electrically isolate the piston or pistons from the surrounding core. The electrically insulating coating is applied to the exterior surface of one or both of the pistons or, alternately, to the inner surface of the core. Electrically insulated, right circular cylindrical pistons are used at both ends of the apparatus resulting in the ability to uniformly compress reaction charges at high temperatures with a much higher length-to-diameter ratio. A ring of electrical insulating material is alternately mounted at the reaction charge end of each piston, with the remaining exterior surface of each piston coated with a thin, elastically insulating layer.

Burns et al., in U.S. Pat. No. 5,980,852, disclose a reaction vessel for use in producing large diamond crystals of good quality and yield including a reaction volume and a reaction mass located in the volume. The reaction mass comprises a plurality of seed particles located in or on a surface in the reaction volume and a carbon source separated from the seed particles by a mass of metallic catalyst/solvent for diamond synthesis. The mass comprises alternating layers of carbon-rich and carbon-lean metallic catalyst/solvent that lie parallel or substantially parallel to the surface. There is also a mass of alternating layers of carbon-rich and carbon-lean metallic catalyst/solvent within the volume.

Sumiya et al., in U.S. Pat. No. 6,030,595, disclose a high purity synthetic diamond with less impurities, crystals defects, strains, etc., in which the nitrogen content is at most 10 ppm, preferably at most 0.1 ppm and the boron content is at most 1 ppm, preferably at most 0.1 ppm or in which nitrogen atoms and boron atoms are contained in the crystal and the difference between the number of the nitrogen atoms and that of the boron atoms is at most 1×10¹⁷ atoms/cm³. The strain-free synthetic diamond is produced by a process for the production of a strain-free synthetic diamond by the temperature gradient method, which comprises using a carbon source having a boron content of at most 10 ppm and a solvent metal having a boron content of at most 1 ppm and adding a nitrogen getter to the solvent metal, thereby synthesizing the diamond.

Additionally, a diamond's color, electrical and mechanical properties are affected by different variables, most commonly the nitrogen content. The most easily detected property affected by nitrogen content is a diamond's color. To a lesser degree, the content levels of other materials within the diamond affect its characteristics. For example, boron is much less common than nitrogen, but when it replaces individual carbon atoms in a diamond, the diamond's electrical conductivity and color are changed.

The apparatuses currently used for producing synthetic diamonds and other ultra-hard materials by way of the application of high pressure and high temperature have not been able to control the content of impurities such as nitrogen and boron of synthesized diamonds in a way that a user can more easily control the color or mechanical or electrical properties of the synthetic diamond. Thus, it is important to be able to provide ideal production conditions in the apparatus in order to ensure the desired growth and quality of the synthetic diamond.

### BRIEF SUMMARY OF THE INVENTION

The above-identified drawbacks can be solved by an embodiment of the present inventive subject matter in which an apparatus for growing a synthetic diamond comprises a reaction area in a high pressure, high temperature apparatus; and a means for pulling a vacuum on said reaction area to remove gaseous impurities. The means for pulling a vacuum comprises a means selected from the group consisting of a diffusion pump, a vane pump, a rotary piston pump, a direct drive pump, a belt drive pump, a screw pump and combinations thereof. In an aspect of the inventive subject matter, the means for pulling a vacuum comprises a diffusion pump.

Also, the present inventive subject matter includes a method of controlling at least one property of a synthetic diamond comprising the steps of: a) providing a seed, a source of carbon and a solvent/catalyst for said synthetic diamond growth in a reaction core; b) positioning said reaction core in a reaction area of a high pressure, high temperature apparatus; c) evacuating said reaction area to remove gaseous impurities using means for pulling a vacuum; and d) subjecting the reaction core to isothermal conditions of elevated temperature and pressure for a period of time suitable for growing said synthetic diamond; wherein said evacuation step is accomplished by pulling a vacuum from about −5 to about −30 inches of mercury for a time sufficient to remove at least 50% of nitrogen in said reaction core. While the present application indicates the amount of vacuum pulled as inches of mercury, it is contemplated that other units of measurement, including without limitation Torr and atmospheres, are also within the scope of the present inventive subject matter.

This inventive method also includes pulling said vacuum from about −20 to about −30 inches of mercury. In another aspect, the vacuum is pulled to about −29 inches of mercury. Alternatively, the means for pulling a vacuum in the inventive method comprises a means selected from the group consisting of a diffusion pump, a vane pump, a rotary piston pump, a direct drive pump, a belt drive pump, a screw pump and combinations thereof, wherein said means for pulling a vacuum is preferably a diffusion pump. The controllable property is selected from the group consisting of color, nitrogen content, refractive index, dispersion, optical transmission, thermal conductivity, electrical conductivity, mechanical properties, and combinations thereof.

An additional method of controlling at least one property of a synthetic diamond, comprises providing a seed, a source of carbon and a solvent/catalyst for said synthetic diamond growth in a reaction core; positioning said reaction core in a reaction area of a high pressure, high temperature apparatus; charging said reaction area with a gas; subjecting the reaction core to isothermal conditions of elevated temperature and pressure for a period of time suitable for growing said synthetic diamond; wherein said gas is selected from the group consisting of nitrogen, oxygen, boron, phosphorous, hydrogen, chlorine, fluorine, helium, xenon, krypton, neon, argon, arsenic and mixtures thereof. In one aspect, the gas used to charge the reaction area is nitrogen. The at least one property is selected from the group consisting of color, nitrogen content, refractive index, dispersion, optical transmission, thermal conductivity, electrical conductivity, or some combination thereof.

A further embodiment of the present inventive subject matter is directed to an apparatus for growing a synthetic diamond comprising: a) a reaction area in a high pressure, high temperature apparatus, said reaction area being where said synthetic diamond is grown; and b) means for pulling a vacuum to remove gaseous impurities from said reaction area or for introducing at least one material into said reaction area.

An even further embodiment of the present inventive subject matter is directed to an apparatus for growing a synthetic diamond comprising: a) a reaction area in a high pressure, high temperature apparatus, said reaction area being where said synthetic diamond is grown; b) means for pulling a vacuum on said reaction area to remove gaseous impurities; and c) means for introducing at least one material in said reaction area.

A still even further embodiment of the present inventive subject matter is directed to a method of controlling at least one property of a synthetic diamond, comprising: a) providing a seed, a source of carbon and a solvent/catalyst for said synthetic diamond growth in a reaction core; b) positioning said reaction core in a reaction area of a high pressure, high temperature apparatus; c) pulling a vacuum on said reaction area while simultaneously charging said reaction area with a gas or a liquid under pressure; d) subjecting the reaction core to isothermal conditions of elevated temperature and pressure for a period of time suitable for growing said synthetic diamond; wherein said gas is selected from the group consisting of nitrogen, oxygen, boron, phosphorous, hydrogen, chlorine, fluorine, helium, xenon, krypton, neon, argon, arsenic and mixtures thereof.

These and other aspects of the invention will be better understood by those of skill in the art with reference to the following drawings wherein like numbers represent like elements throughout the several views.

### BRIEF DESCRIPTION OF THE DRAWINGS

The accompanying drawings illustrate embodiments of the present invention and, together with the description, serve to explain the principles of the invention.

FIG. 1 is a vertical cross-section view of an embodiment of the present inventive subject matter.

FIG. 2 is a chart showing relative nitrogen concentrations in reaction cores with and without a vacuum being pulled.

### DETAILED DESCRIPTION OF EMBODIMENTS OF THE INVENTION

Those of ordinary skill in the art will realize that the following description of the present invention is illustrative only and not in any way limiting.

The present inventive subject matter is directed to an apparatus for growing a synthetic diamond. The apparatus comprises a reaction area in a high pressure, high temperature apparatus. The reaction area is where the synthetic diamond is grown. The apparatus also includes means for pulling a vacuum on the reaction area to remove gaseous impurities. It is contemplated within the scope of the present inventive subject matter that the high pressure, high temperature apparatus is selected from the group consisting of a split-sphere apparatus, a belt-type apparatus, a piston-cylinder apparatus, an annular-die apparatus and a toroid apparatus.

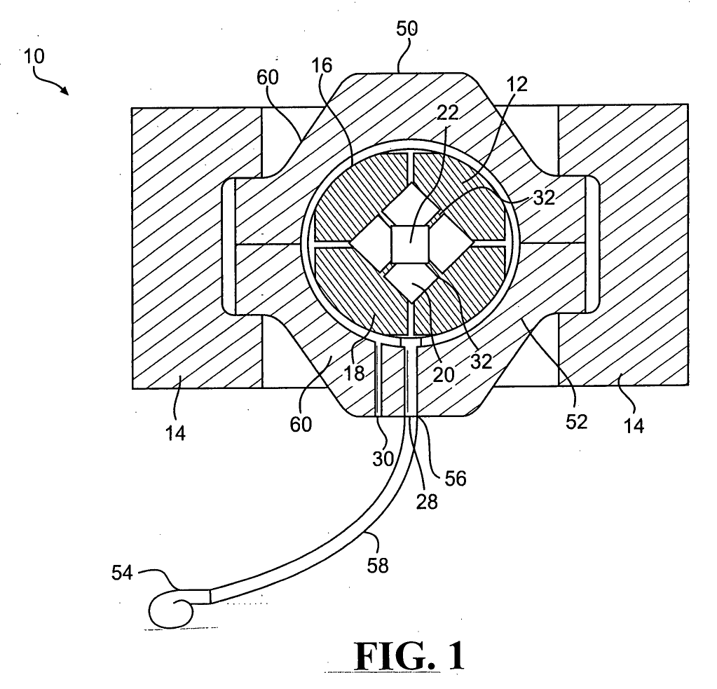

With reference to the Figures, FIG. 1 depicts a vertical cross-sectional view of a split-sphere high pressure, high temperature apparatus 10 in accordance with an embodiment of the present inventive subject matter. The high pressure, high temperature apparatus 10 is comprised of a split-sphere reaction area 12 and a plurality of safety clamps 14 on opposite sides of reaction area 12. Apart and located separate from the high pressure, high temperature apparatus, there exists a means for pulling a vacuum on the reaction area. The means for pulling a vacuum is typically a reversible pump, which is depicted in the Figure as element 54, and is connected to the high pressure, high temperature apparatus through tube 58. The pump can be a diffusion pump, a vane pump, a rotary piston pump, a direct drive pump, a belt drive pump, s screw pump or some combination thereof. In general, the means for pulling a vacuum can comprise any device capable of pulling a vacuum on the reaction area. Preferably, the pump is a diffusion pump.

Reaction area 12 comprises an outer body 60 having a top half 50 and a bottom half 52, with a cavity 16 defined therein. Large dies 18, small dies 20, and a reaction core 22 are positioned with cavity 16. In operation of the reaction area, as top half 50 and bottom half 52 of reaction area 12 are brought together, pressure is applied to large dies 18, which in turn apply pressure to small dies 20. As pressure is applied to small dies 20, the dies apply pressure to reaction core 22.

Prior to being placed in reaction area 12, reaction core 22 is charged with a graphite source, a diamond seed, and a metal solvent/catalyst mixture used to produce a synthetic diamond. Graphite sources, diamond seeds and solvent/metal catalysts are generally known in the art, and any such material is appropriate for use in the apparatus of the present inventive subject matter.

High pressure, high temperature apparatus 10 also contains at least one manifold 28, which allows access to reaction area 12 from outside of apparatus 10. In the embodiment depicted in FIG. 1, manifold 28 is at least a two-way manifold, allowing a user to either draw gases and other substances out of reaction area 12 or introduce different gases or material into the reaction area 12. For example, in this particular embodiment of the apparatus, a reversible pump 54 is attached to the manifold 28 at inlet 56 through tube 58. Through the reversible pump 54, a user can remove impurities from reaction area 12. Alternatively, the flow of reversible pump 54 can be reversed to introduce an inert gas or some other desired gas into the reaction area 12 by way of manifold 28. The advantage to using a manifold rather than multiple inlets is that the number of locations where the chamber is exposed to contamination is kept to a minimum thereby ensuring that the inside of the core and the split sphere chamber can be kept under adequate control.

In operation of the apparatus, the vacuum is pulled on the core before or while the pressure in the core is rising. Vacuum is pulled on the core only before or while the pressure rises because, as a result of the pressurizing step, the core is sealed from the effects of the vacuum. The seal results from the large dies clamping down on the small dies in response to the increased pressure, which in turn seals the core. The reason for pulling the vacuum on the chamber is to remove impurities from the core. Thus, once the core is sealed the ability to remove impurities from the reaction core is greatly diminished.

The means for pulling the vacuum is able to remove the impurities from the reaction area. In one aspect of the present inventive subject matter, the vacuum is pulled on the reaction area for a sufficient time and at a sufficient negative pressure to remove about 50% of the nitrogen in the reaction area. In another aspect, the amount of nitrogen removed is from about 35% to about 50%.

In particular in this embodiment, pulling the vacuum removes air, which is primarily nitrogen gas and oxygen gas, from the reaction core. Also, pulling the vacuum reduces water and other ambient impurities. Nitrogen is the biggest determiner of a diamond's color. By controlling the amount of air, and thus the amount of nitrogen content in the reaction core, a user is able to better control the color of a synthesized diamond. The reversible pump 54 is able to create a negative pressure of between about minus 30 in Hg and about minus 5 in Hg on the reaction core. In an aspect of this embodiment, the pump is able to draw a vacuum of about minus 29 in Hg.

The high pressure, high temperature apparatus 10 in FIG. 1 also includes a second manifold 30, through which oil is introduced into a cavity on the perimeter of reaction area 12. The oil is present to ensure that pressure is applied evenly to each of large dies 18, which also results in pressure being applied evenly to the remaining components in reaction area 12, including small dies 20 and reaction core 22. The oil introduced through manifold 30 is any such oil suitable for use as a pressure medium.

Manifold 28 in the embodiment depicted in FIG. 1 is also used to introduce water into reaction area 12. Water is necessary to cool and maintain the temperature of large dies 18 and small dies 20. Water is circulated around large dies 18 and small dies 20; however, gaskets 32 are positioned between adjacent small dies 20 and seal reaction core 22 so that water does not reach reaction core 22.

In an alternative aspect of this embodiment of the present inventive subject matter, the high pressure, high temperature apparatus also includes means for introducing at least one material into the reaction area of the apparatus. The material introduced into the reaction area is a gas as further defined below, a liquid or a combination of gas and liquid. The means for introducing the material into the reaction area is separate from the means for pulling a vacuum, or the means for introducing the material may be the same means used for pulling the vacuum.

With respect to the dies 18 and 20, there are typically eight large dies 18 surrounding six small dies 20 in a split-sphere high pressure, high temperature apparatus. Materials suitable for making the large dies 18 include processed steel and tungsten carbide. Likewise, materials suitable for making the small dies 20 also include processed steel and tungsten carbide. In another aspect of this embodiment, the small dies are made from tungsten carbide.

Other high pressure, high temperature apparatuses are also usable in the present inventive subject matter. Examples of other high pressure, high temperature apparatuses include, without limitation, a belt-type apparatus, a piston-cylinder apparatus, an annular-die apparatus and a toroid apparatus. Each type of high pressure, high temperature apparatus is well-known in the art. For example, U.S. Pat. No. 4,301,134 to Strong describes a belt-type high pressure, high temperature apparatus usable in the present inventive subject matter, while U.S. Pat. No. 5,244,368 to Frushour describes a non-limiting example of a piston-cylinder high pressure, high temperature apparatus that is also usable in the present inventive subject matter. Likewise, U.S. Pat. No. 4,518,334 describes an annular-die high pressure, high temperature apparatus employable in the present inventive subject matter. Further, U.S. Pat. No. 4,290,741 to Kolchin et al. and U.S. Patent Application Publication No. 2004/0134415 to D'Evelyn et al. disclose toroid high pressure, high temperature apparatuses that are usable in the present inventive subject matter. The contents of each of the above-listed U.S. patents and published patent applications are hereby incorporated in their entirety.

Prior to being placed in the reaction area of each type of high pressure, high temperature apparatus, a reaction core is charged with a graphite source, a diamond seed, and a metal solvent/catalyst mixture used to produce a synthetic diamond. Graphite sources, diamond seeds and solvent/metal catalysts are generally known in the art, and any such material is appropriate for use in the apparatus of the present inventive subject matter.

Each type of high pressure, high temperature apparatus described above includes a reaction area defined by the anvils or dies used to apply pressure in the apparatus. The reaction area for each type of apparatus comprises a reaction core in which the synthetic diamond is grown, as well as a plurality of dies or anvils positioned to apply pressure to the reaction core. The present inventive subject matter contemplates constructing a high pressure, high temperature apparatus selected from the group listed above and including means for evacuating the gaseous impurities from the reaction area or charging the reaction area with a gas or liquid under pressure. The present inventive subject matter contemplates that each type of high pressure, high temperature apparatus is capable of being fitted with the components necessary for pulling a vacuum on the reaction area, or for charging the reaction area with a gas or liquid, or for accomplishing both pulling a vacuum and charging a gas or liquid.

The present inventive subject matter is also directed to a method of controlling at least one property of a synthetic diamond by pulling a vacuum on a reaction area of a high pressure/high temperature apparatus (hereinafter referred to as “an HP/HT apparatus”). The method includes the steps of: 1) providing a seed, a source of carbon, and a solvent/catalyst for synthetic diamond growth in a reaction core of a split-sphere chamber; 2) positioning the reaction core in a reaction area of a high pressure high temperature apparatus; 3) evacuating the reaction area by using a means for pulling a vacuum on the reaction area; 4) applying heat and pressure to the reactor core for a period of time suitable to grow a synthetic diamond; and 5) removing the diamond to put it through finishing steps. The negative pressure created by the vacuum in step 3) is between about minus 30 to minus 5 inches of Hg and is applied for a time sufficient to remove at least half of the nitrogen in the reaction area. Alternatively, an acceptable range of negative pressure in step 3 is between about minus 30 to about minus 20 inches of Hg. In a further aspect of this embodiment, the negative pressure is at minus 29 inches of Hg. The vacuum is capable of removing up to about 50% of the nitrogen out of the reaction core due to the fact that the raw materials have a porous structure, with the impurities entrained in the pores. The impurities are distributed such that only the impurities in the pores on the surface of the raw materials can be removed, while the vacuum does not affect the pores on the inside of the raw materials, including the graphite source, the metal solvent/catalyst and the diamond seed.

The present inventive method may be practiced in a high pressure, high temperature apparatus selected from the group consisting of a split-sphere apparatus, a belt-type apparatus, a piston-cylinder apparatus, an annular-die apparatus and a toroid apparatus. The apparatus used in the inventive method comprises a reaction area that includes a reaction core and a plurality of dies or anvils positioned to apply pressure to the reaction core. In a non-limiting example, the present inventive method is accomplished using an apparatus as depicted in FIG. 1 and as described above. Particularly, the apparatus has a reaction area having an outer body, which has a cavity formed therein. The apparatus also has a reaction core and a plurality of dies positioned to apply pressure to the reaction core. The reaction core and the plurality of dies are located within the cavity. In particular, the plurality of dies comprise a plurality of small dies that are adjacent to the reaction core and a plurality of large dies that surround the plurality of small dies. The means used to pull the vacuum in step 3 may be reversible and is selected from the group consisting of a diffusion pump, a vane pump, a rotary piston pump, a direct drive pump, a belt drive pump, a screw pump or some combination thereof. Preferably, the means is a diffusion pump. However, the method may also be accomplished using any of the high pressure, high temperature apparatuses described above.

The properties of the synthesized diamond that can be controlled by this method include color, nitrogen content, refractive index, dispersion, optical transmission, thermal conductivity, and electrical conductivity. As few as one, or as many as all, of these properties can be controlled using by pulling a vacuum on the reaction core. These properties are affected by the amount of impurities found in the finished synthetic diamond, in particular, the amount of nitrogen. The various properties are controlled according to the present inventive subject matter by controlling the amount of impurities in the reaction core available for inclusion into the synthetic diamond. For example, as with color, the refractive index of the synthetic diamond is affected by the amount of nitrogen in the diamond, i.e. the more nitrogen that is present, the greater the refractive index is. Thus, the refractive index can be controlled by controlling the amount of nitrogen available to the synthetic diamond as it grows.

As suggested above, pulling the vacuum removes the air, which is primarily nitrogen gas and oxygen gas, from the core and also reduces other ambient impurities, including water. Specifically, nitrogen is the biggest determiner of a diamond's color. However, the presence of nitrogen is not without its benefits. For example, the less nitrogen present, the harder it is to grow a diamond. Also, nitrogen helps to speed the growth of the diamond and helps to keep metal inclusions in the synthetic diamond to a minimum. Due to the effects of nitrogen on the color of a diamond, it is an object of the present inventive method to control the nitrogen content of the core and the split sphere chamber in general.

The present inventive method results in orange, yellow, clear, blue or pink diamonds. In an orange diamond, the nitrogen content is between 60 ppm and 100 ppm. Producing an orange diamond does not necessarily require that a vacuum be pulled on the core. Similarly, in a yellow diamond the nitrogen content is between 10 ppm and 30 ppm. And in clear, blue and pink diamonds, the nitrogen content is less than 10 ppm. For the production of yellow, clear, blue and pink diamonds according to the present inventive subject matter, a vacuum is pulled on the core or the split sphere chamber to reach the desired nitrogen levels.

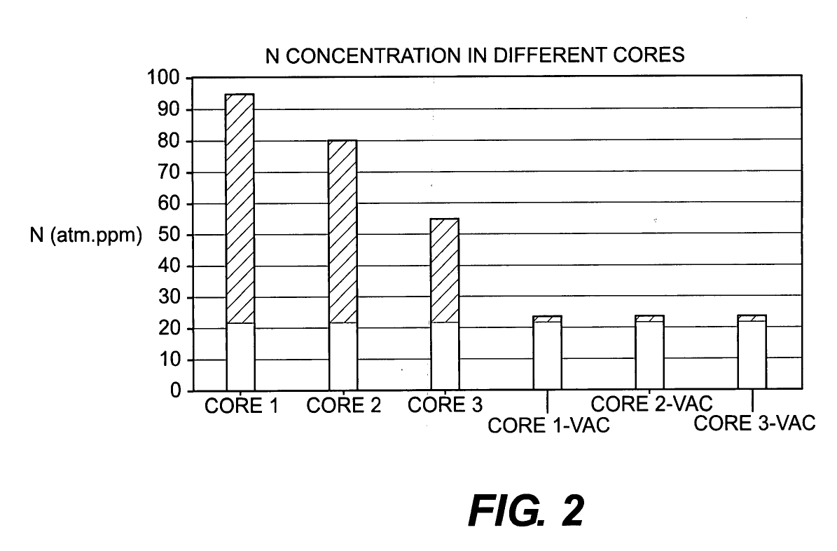

FIG. 2 shows the relative nitrogen concentrations of three different production reaction cores with and without a vacuum being pulled on the reaction cores. Each core is charged with a different graphite source, a diamond seed, and a mixture of metal catalysts/solvents. The amount of nitrogen in each reaction core was measured with pulling a vacuum and without pulling a vacuum. As can be seen in FIG. 2, each core had a different nitrogen concentration where no vacuum was pulled. This is due to the different amounts and types of material present. However, when a vacuum was pulled on each core, it can be seen that each core had the same amount of nitrogen present, irrespective of the amounts and types of starting materials used. Further, the amount of nitrogen present in the reaction cores subjected to the vacuum was much less than that of the original concentration.

Another embodiment of the present inventive subject matter is directed to a method of controlling at least one property of a synthetic diamond. This method includes the steps of: 1) providing a seed, a source of carbon, and a solvent/catalyst for synthetic diamond growth in a reaction core; 2) positioning the reaction core in a reaction area of a high pressure/high temperature apparatus; 3) charging the reaction area with a gas selected from the group consisting of nitrogen, oxygen, boron, phosphorous, hydrogen, chlorine, fluorine, helium, xenon, krypton, neon, argon, arsenic and mixtures thereof; 4) applying heat and pressure to the reactor core for a period of time suitable to grow a synthetic diamond; and 5) removing the diamond to put it through finishing steps. In an aspect of this embodiment, the gas used in step 3 to charge the chamber is nitrogen.

In an aspect of the inventive subject matter, the gas (or liquid) charged to the reaction area is done under pressure. The pressure under which the gas or liquid is charged to the reaction area is from about 0 to about 100 pounds per square inch (psi). In another aspect, the pressure is about 25 to about 75 psi. In a further aspect, the pressure is about 50 psi.

It is contemplated that this embodiment is practiced in an apparatus as described above. The present inventive method may be practiced in a high pressure, high temperature apparatus selected from the group consisting of a split-sphere apparatus, a belt-type apparatus, a piston-cylinder apparatus, an annular-die apparatus and a toroid apparatus. The apparatus used in this inventive embodiment comprises a reaction area that includes a reaction core and a plurality of dies or anvils positioned to apply pressure to the reaction core. In a non-limiting example, the present inventive method is accomplished using an apparatus as depicted in FIG. 1 and as described above. Particularly, the apparatus has a reaction area having an outer body, which has a cavity formed therein. The apparatus also has a reaction core and a plurality of dies positioned to apply pressure to the reaction core. The reaction core and the plurality of dies are located within the cavity. In particular, the plurality of dies comprise a plurality of small dies that are adjacent to the reaction core and a plurality of large dies that surround the plurality of small dies. The means used to pull the vacuum in step 3 may be reversible and is selected from the group consisting of a diffusion pump, a vane pump, a rotary piston pump, a direct drive pump, a belt drive pump, a screw pump or some combination thereof. Preferably, the means is a diffusion pump. However, the method may also be accomplished using any of the high pressure, high temperature apparatuses described above.

This additional inventive method involves introducing additional materials into the reaction area to influence the characteristics of the synthesized diamond. For example, gas doping of the reaction core can help influence the color of the synthetic diamond. Gas doping can be done with or without first pulling a vacuum as described above. However, for clear, blue, and pink diamonds, which must have a nitrogen content of less than 10 ppm, a vacuum is first pulled prior to introducing the dopant into the reaction area. Typically, gas doping is used to synthesize blue diamonds. Blue diamonds are produced by introducing a predetermined amount of boron into the reaction core. The amount of boron needed to produce a blue diamond is less than 10 ppm.

A means for pulling a vacuum can be applied to the reaction area separately from the means for charging the reaction area. In this manner, the means for pulling the vacuum is applied in the manner disclosed above with respect to the previous embodiment in order to control the properties of the synthetic diamond such as nitrogen and the means for charging the reaction area can be applied before, after or simultaneously with the means for pulling the vacuum. To facilitate simultaneous application of both means, a second pump (not shown) selected from the group consisting of a diffusion pump, a vane pump, a rotary piston pump, a direct drive pump, a belt drive pump, a screw pump or some combination thereof is applied, for example, to the manifold. In this instance, however, the manifold will have at least two tubes so that both means can be connected to the core reactor. As suggested above, pulling the vacuum removes the air, which is primarily nitrogen gas and oxygen gas, from the core and also reduces ambient impurities, such as water. Specifically, nitrogen is the biggest determiner of a diamond's color.

Pulling a vacuum on the core is done before or while the pressure in the core is rising. The need for pulling a vacuum on the core only before or while the pressure rises is because as a result of the pressurizing step, the core is sealed from the effects of the vacuum. The seal results from the large dies clamping down on the small dies in response to the increased pressure, which in turn seals the core. The reason for pulling the vacuum on the chamber in the first place is to remove impurities from the core. Thus, once the core is sealed the ability to remove nitrogen is greatly diminished.

Due to the effects of nitrogen on the color of a diamond, it is an aspect of the present inventive method to control the nitrogen content of the core and the split sphere chamber in general. In particular, an advantage to the present inventive method is that the color of the finished diamond can be controlled. The present inventive method can produce orange, yellow, clear, blue or pink diamonds. In an orange diamond, the nitrogen content is between 60 ppm and 100 ppm.

The properties that can be controlled by this additional inventive method are color, nitrogen content, refractive index, dispersion, optical transmission, thermal conductivity, and electrical conductivity as described above. As few as one, or as many of all, of these properties can be controlled using by pulling a vacuum on the reaction core 16. In particular, color can be controlled

Lastly, the diamond is removed from the high pressure, high temperature apparatus to conduct finishing steps such as cutting and polishing. Also, to ensure that the method is being followed properly, the diamond can be put through tests to determine its nitrogen content, clarity, brilliance, etc. Thus, if necessary, the high pressure, high temperature apparatus can be adjusted accordingly.

The present inventive subject matter is further directed to an apparatus for growing a synthetic diamond comprising a reaction area in a high pressure, high temperature apparatus. The reaction area is the location in the high pressure, high temperature apparatus where the synthetic diamond is grown. The apparatus also includes means for pulling a vacuum to remove gaseous impurities from the reaction area or for introducing at least one material into the reaction area. The particulars of this embodiment include the details discussed above with respect to the other embodiments directed to present inventive apparatuses. In particular, the high pressure, high temperature apparatus of this embodiment is selected from the group consisting of a split-sphere apparatus, a belt-type apparatus, a piston-cylinder apparatus, an annular-die apparatus and a toroid apparatus, the details of which are described above.

In an alternative embodiment, the present inventive subject matter is further drawn to an apparatus for growing a synthetic diamond comprising a reaction area in a high pressure, high temperature apparatus, means for pulling a vacuum on the reaction area to remove gaseous impurities, and means for introducing at least one material in the reaction area. The reaction area is where the synthetic diamond is grown. As with the above embodiment, the particulars of this embodiment include the details discussed above with respect to the other embodiments directed to present inventive apparatuses. In particular, the high pressure, high temperature apparatus of this embodiment is selected from the group consisting of a split-sphere apparatus, a belt-type apparatus, a piston-cylinder apparatus, an annular-die apparatus and a toroid apparatus, the details of which are described above.

In a still further embodiment, the present inventive subject matter is directed to a method of controlling at least one property of a synthetic diamond. The method comprises the steps of a) providing a seed, a source of carbon and a solvent/catalyst for the synthetic diamond growth in a reaction core; b) positioning the reaction core in a reaction area of a high pressure, high temperature apparatus; c) pulling a vacuum on the reaction area while simultaneously charging the reaction area with a gas or a liquid under pressure; d) subjecting the reaction core to isothermal conditions of elevated temperature and pressure for a period of time suitable for growing the synthetic diamond. The pressure under which the gas or liquid is charged to the reaction area is from about 0 to about 100 pounds per square inch (psi). In another aspect, the pressure is about 25 to about 75 psi. In a further aspect, the pressure is about 50 psi.

The gas or liquid charged to the reaction area is selected from the group consisting of nitrogen, oxygen, boron, phosphorous, hydrogen, chlorine, fluorine, helium, xenon, krypton, neon, argon, arsenic and mixtures thereof. In addition, the high pressure, high temperature apparatus of this embodiment is selected from the group consisting of a split-sphere apparatus, a belt-type apparatus, a piston-cylinder apparatus, an annular-die apparatus and a toroid apparatus, the details of which are described above.

The inventive subject matter being thus described, it will be recognized that the same may be varied in many ways. Such variations are not to be regarded as a departure from the spirit and scope of the inventive subject matter, and all such modifications are intended to be included within the scope of the following claims.

I claim:

1. An apparatus for growing a synthetic diamond comprising:
a) a reaction area in a high pressure, high temperature apparatus, said reaction area being where said synthetic diamond is grown; and
b) means for pulling a vacuum on said reaction area to remove gaseous impurities.

2. The apparatus according to claim 1 wherein said high pressure, high temperature apparatus is selected from the group consisting of a split-sphere apparatus, a belt-type apparatus, a piston-cylinder apparatus, an annular-die apparatus and a toroid apparatus.

3. The apparatus according to claim 2 wherein said reaction area comprises a reaction core and a plurality of dies or anvils positioned to apply pressure to said reaction core.

4. The apparatus according to claim 2 wherein said high pressure, high temperature apparatus is a split-sphere apparatus.

5. The apparatus according to claim 4, wherein said reaction area comprises an outer body having a cavity formed therein, a reaction core and a plurality of dies positioned to apply pressure to said reaction core, said reaction core and said plurality of dies located within said cavity.

6. The apparatus according to claim 5 wherein said plurality of dies comprises a plurality of small dies adjacent to said reaction core and a plurality of large dies surrounding said plurality of small dies.

7. The apparatus according to claim 1 wherein said means for pulling a vacuum comprises a means selected from the group consisting of a diffusion pump, a vane pump, a rotary piston pump, a direct drive pump, a belt drive pump, a screw pump and combinations thereof.

8. The apparatus according to claim 6 wherein said means for pulling a vacuum comprises a diffusion pump.

9. The apparatus according to claim 1 further comprising means for introducing at least one material into said reaction area.

10. A method of controlling at least one property of a synthetic diamond, comprising:
a) providing a seed, a source of carbon and a solvent/catalyst for said synthetic diamond growth in a reaction core;
b) positioning said reaction core in a reaction area of a high pressure, high temperature apparatus;
c) evacuating said reaction area to remove gaseous impurities using means for pulling a vacuum;
d) subjecting the reaction core to isothermal conditions of elevated temperature and pressure for a period of time suitable for growing said synthetic diamond;
wherein said evacuation step is accomplished by pulling a vacuum from about −1 to about −30 inches of mercury for a time sufficient to remove at least 50% of nitrogen in said reaction core.

11. The method according to claim 10 wherein said vacuum is pulled from about −20 to about −30 inches of mercury.

12. The method according to claim 11 wherein said vacuum is pulled at about −29 inches of mercury.

13. The method according to claim 10 wherein said high pressure, high temperature apparatus is selected from the group consisting of a split-sphere apparatus, a belt-type apparatus, a piston-cylinder apparatus, an annular-die apparatus and a toroid apparatus.

14. The method according to claim 13 wherein said reaction area comprises a reaction core and a plurality of dies or anvils positioned to apply pressure to said reaction core.

15. The method according to claim 13 wherein said high pressure, high temperature apparatus is a split-sphere apparatus.

16. The method according to claim 15 wherein said reaction area comprises an outer body having a cavity formed therein, said reaction core and a plurality of dies positioned to apply pressure to said reaction core, said reaction core and said plurality of dies located within said cavity.

17. The method according to claim 16 wherein said plurality of dies comprises a plurality of small dies adjacent to said reaction core and a plurality of large dies surrounding said plurality of small dies.

18. The method according to claim 10 wherein said means for pulling a vacuum comprises a means selected from the group consisting of a diffusion pump, a vane pump, a rotary piston pump, a direct drive pump, a belt drive pump, a screw pump and combinations thereof.

19. The method according to claim 18 wherein said means for pulling a vacuum comprises a diffusion pump.

20. The method according to claim 10 wherein said at least one property is selected from the group consisting of color, nitrogen content, refractive index, dispersion, optical transmission, thermal conductivity, electrical conductivity, mechanical properties, and combinations thereof.

21. The method according to claim 20 wherein said at least one property is color.

22. A method of controlling at least one property of a synthetic diamond, comprising:
a) providing a seed, a source of carbon and a solvent/catalyst for said synthetic diamond growth in a reaction core;
b) positioning said reaction core in a reaction area of a high pressure, high temperature apparatus;
c) charging said reaction area with a gas or a liquid;
d) subjecting the reaction core to isothermal conditions of elevated temperature and pressure for a period of time suitable for growing said synthetic diamond;
wherein said gas is selected from the group consisting of nitrogen, oxygen, boron, phosphorous, hydrogen, chlorine, fluorine, helium, xenon, krypton, neon, argon, arsenic and mixtures thereof.

23. The method according to claim 22 wherein said gas is nitrogen.

24. The method according to claim 22 wherein said high pressure, high temperature apparatus is selected from the group consisting of a split-sphere apparatus, a belt-type apparatus, a piston-cylinder apparatus, an annular-die apparatus and a toroid apparatus.

25. The method according to claim 24 wherein said reaction area comprises a reaction core and a plurality of dies or anvils positioned to apply pressure to said reaction core.

26. The method according to claim 24 wherein said high pressure, high temperature apparatus is a split-sphere apparatus.

27. The method according to claim 26 wherein said reaction area comprises an outer body having a cavity formed therein, said reaction core and a plurality of dies positioned to apply pressure to said reaction core, said reaction core and said plurality of dies located within said cavity.

28. The method according to claim 27 wherein said plurality of dies comprises a plurality of small dies adjacent to said reaction core and a plurality of large dies surrounding said plurality of small dies.

29. The method according to claim 22 wherein said reaction area is charged using a means selected from the group consisting of a diffusion pump, a vane pump, a rotary piston pump, a direct drive pump, a belt drive pump, a screw pump and combinations thereof.

30. The method according to claim 29 wherein said means for charging said reaction area comprises a diffusion pump.

31. The method according to claim 22 wherein said at least one property is selected from the group consisting of color, nitrogen content, refractive index, dispersion, optical transmission, thermal conductivity, electrical conductivity, mechanical properties, and combinations thereof.

32. The method according to claim 31 wherein said at least one property is color.

33. The method according to claim 22 further including the step of pulling a vacuum on the reaction core using a means for pulling the vacuum.

34. The method according to claim 33 wherein said means for pulling a vacuum on the reaction core is selected from the group consisting of a diffusion pump, a vane pump, a rotary piston pump, a direct drive pump, a belt drive pump, a screw pump and combinations thereof.

35. The method according to claim 34 wherein said means for pulling a vacuum on the reaction core is integrated with said means for charging the reaction core.

36. The method according to claim 34 wherein said means for pulling a vacuum on the reaction core is separate from said means for charging said reaction area.

37. An apparatus for growing a synthetic diamond comprising:
a) a reaction area in a high pressure, high temperature apparatus, said reaction area being where said synthetic diamond is grown; and
b) means for pulling a vacuum to remove gaseous impurities from said reaction area or for introducing at least one material into said reaction area.

38. An apparatus for growing a synthetic diamond comprising:
a) a reaction area in a high pressure, high temperature apparatus, said reaction area being where said synthetic diamond is grown;
b) means for pulling a vacuum on said reaction area to remove gaseous impurities; and
c) means for introducing at least one material in said reaction area.

39. A method of controlling at least one property of a synthetic diamond, comprising:
a) providing a seed, a source of carbon and a solvent/catalyst for said synthetic diamond growth in a reaction core;
b) positioning said reaction core in a reaction area of a high pressure, high temperature apparatus;
c) pulling a vacuum on said reaction area while simultaneously charging said reaction area with a gas or a liquid under pressure;
d) subjecting the reaction core to isothermal conditions of elevated temperature and pressure for a period of time suitable for growing said synthetic diamond;
wherein said gas is selected from the group consisting of nitrogen, oxygen, boron, phosphorous, hydrogen, chlorine, fluorine, helium, xenon, krypton, neon, argon, arsenic and mixtures thereof.
